(19) United States
(12) Patent Application Publication
(10) Pub. No.: US 2026/0126489 A1
(43) Pub. Date: May 7, 2026

(54) COMPUTER-IMPLEMENTED METHOD FOR PREDICTING A BROKEN BAR DEFECT IN A THREE-PHASE MOTOR

(71) Applicants: PETRÓLEO BRASILEIRO S.A. - PETROBRAS, Rio de Janeiro (BR); UNIVERSIDADE FEDERAL DO ESPÍRITO SANTO - UFES, Vitória (BR); SEVEN SCIENCE SYSTEMS LTDA, Vila Velha (BR)

(72) Inventors: Marcos Leonardo RAMOS, São José dos Campos (BR); Lucas Frizera ENCARNAÇÃO, Vitória (BR); Waldemar Junior TOZI, Vila Velha (BR); Abrahao Da Silva FONTES, Vitória (BR); Claudine Santos BADUE, Vitória (BR); Thiago Oliveira Dos Santos, Vitória (BR); Ronimar Espindula VOLKERS, Vila Velha (BR); Ramon Pereira DOS SANTOS, Vitória (BR); Gabriel Braga Ladislau, Vitória (BR); Marlon Moratti do Amaral, Vitória (BR); Alberto Ferreira De Souza, Vitória (BR); Daniel Carletti, Fátima (BR)

(21) Appl. No.: 19/373,060

(22) Filed: Oct. 29, 2025

(30) Foreign Application Priority Data
Nov. 5, 2024 (BR) 1020240230523

(51) Int. Cl. G01R 31/34; G01M 13/00

(52) U.S. Cl. CPC G01R 31/343; G01M 13/00

(57) ABSTRACT

The proposed technique consists of a computer-implemented method for predicting broken bar failures in three-phase motors based on artificial intelligence. Motor vibration, ambient temperature and humidity, and current parameters in each phase are used as inputs in a previously trained Artificial Intelligence (AI) to determine the probability of broken bar failure in each phase. Furthermore, an FFT is performed on each current to determine its fundamental frequency and perform windowing to the left and right of the fundamental frequency, extracting parameters such as mean value, standard deviation, maximum value, minimum value, kurtosis, skewness, and spacing from each window. These parameters are also used as inputs in the previously trained AI.

### CROSS REFERENCE TO RELATED APPLICATIONS

The present application claims priority to BR patent application Ser. No. 1020240230523 filed on Nov. 5, 2024, which is hereby incorporated by reference in its entirety.

### FIELD OF THE INVENTION

The present invention relates to electrical engineering. More specifically, the present invention describes an artificial intelligence-based method for automatically and objectively predicting the probability of a broken bar failure in a three-phase motor.

### BACKGROUND OF THE INVENTION

Modern industrial activity currently depends on energy-efficient and operationally efficient equipment. Generally speaking, electric motors represent a significant portion of the equipment responsible for producing mechanical energy for a wide range of industrial processes. Despite being robust, they can show defects inherent to their operation, even when a comprehensive maintenance plan is strictly followed. Defects that can cause industrial process shutdowns are not always easily overcome with an appropriate maintenance plan. To circumvent this problem and avoid unscheduled downtime, prescriptive diagnostics are usually employed. This involves monitoring and analyzing the operating conditions of the equipment and electrical and physical signals to assess the presence of a fault or predict the possibility of a future fault.

Even with the most modern fault analysis equipment available on the market, it is still necessary to rely on the expertise of the technician who interprets these signals. However, this process is costly in both time and money.

### STATE OF THE ART

The document CN 117928642 A, entitled “State Monitoring and Fault Diagnosis System for Motor Rolling Bearings”, describes a condition monitoring and fault diagnosis system for motor bearings, comprising a data acquisition side, a server side, and a data display side. The data acquisition side is used to collect data from multiple measurement points on the motor bearing according to a predefined data sampling frequency to obtain a raw data set and monitor data from video. The server side is used to receive the original data set sent by the data acquisition side and perform data preprocessing and analysis on the original data set to obtain a set of important data information. The server side is also used to determine the operating status of the motor bearing using this set of important data information and to perform fault analysis on the abnormally operating motor bearing to determine the type of fault.

The document CN 117269752 A, titled “An Operating Status Monitoring Device and Method Suitable for Three-Phase High-Voltage Asynchronous Motors”, discloses an operating status monitoring device suitable for a three-phase high-voltage asynchronous motor, including a switching power supply module to supply power to the operating status monitoring device; a three-phase voltage sampling circuit to collect real-time values of the three-phase voltage; and a current sampling circuit. The three-phase current sampling circuit uses an external high-precision open-type current sensor to collect real-time values of three-phase currents. A high-speed sampling module collects real-time values of three-phase voltages and currents. The values are converted into digital signals. A processor module connected to the high-speed sampling module analyzes the operating status of the high-voltage three-phase asynchronous motor based on the received digital signal and determines whether the high-voltage three-phase asynchronous motor has a fault and the severity of the fault. The analysis results are transmitted through the communication module. The data storage module is used for recording timing waves, recording fault waves, and storing fixed values and parameters.

### SUMMARY OF THE INVENTION

The present invention aims to provide a computer-implemented method capable of analyzing the operating status of an electric motor, diagnosing possible defects and/or imminent failures, and producing comprehensive reports with suggestions for corrective and mitigating actions to postpone a failure until it is possible to schedule a maintenance shutdown.

The invention aims to eliminate subjectivity in the diagnosis of electric motor failures caused by technicians. The computer-implemented method described here adds value to the production chain of processes involving motors by prescriptively detecting defects and their severity. This improves fault analysis and diagnosis, supports decision-making, and empowers field teams with rapid and accurate diagnosis, significantly reducing the costs of corrective and predictive maintenance and equipment acquisition. The unique feature of this invention is the implementation of machine learning and artificial intelligence to complement the current signature technique for fault analysis, fault prediction, and prescription. Also included is the module for Classifying Rotor Broken Bars of Induction Motors with Synthetic Data, an approach that leverages artificial noise-augmented data, eliminating the reliance on real-world data from faulty induction motors, enabling robust results in the detection and classification of broken bars. Field data, historical analysis of motors, and their behavior are stored in a database, fostering the continuous identification of new faults and corrective actions in an integrated manner, through continuous learning proposed by data interaction. Similarly, new studies can be conducted with the acquired fundamental variables, in addition to voltage and current, such as temperature, vibration, and humidity, to infer motor failure prediction. These variables will enable the identification of faults and critical situations previously dependent on the interpretation of specialist technicians, enabling correlational analysis between areas, equipment, and applications. The information is made available on-premises (storage and learning server), ensuring transparent access to the history of acquired and processed data, thus enabling analysis of motor depreciation and opening possibilities for continuous improvements in operational mode and maintenance frequency.

### BRIEF DESCRIPTION OF THE DRAWINGS

The present invention will be described below with reference to its typical embodiments and also with reference to the accompanying drawings.

FIG. 1 is a representation of the spacing of the side fins according to the present invention.

FIG. 2 is a representation of the current signal versus time according to the present invention.

FIG. 3A is an FFT representation of the signal with a natural logarithm according to the present invention.

FIG. 3B is a representation of the flattened FFT according to the present invention.

FIG. 4 is a representation of the windowing of the flattened FFT according to the present invention.

FIG. 5 is a representation of the level of correlation between the variables according to the present invention.

FIG. 6 is a representation of a boxplot of the current, using the F1 Score macro, divided by torque, according to the present invention.

FIG. 7 is a representation of a boxplot of voting for three currents, using the F1 Score macro, divided by torque, according to the present invention.

FIG. 8 is a representation of a boxplot of the average between currents, using the F1 Score macro, divided by torque, according to the present invention.

FIG. 9 is a representation of a bar graph representing the median of the balanced accuracy in the torque configuration (i.e., in the configuration wherein measurements were made for different torques) according to the present invention.

FIG. 10 is a representation of a bar graph representing the median of the balanced accuracy in the on configuration (i.e., in the configuration wherein measurements are taken after turning the engine on and off a few times) in accordance with the present invention.

FIG. 11 is a representation of a bar graph representing the median of the balanced accuracy in the Artificial versus Real configuration using only the voting of the three currents (IA, IB, and IC) and one current (IA) in accordance with the present invention.

FIG. 12 is a representation of a confusion matrix for the classification of the neural network in the on configuration using one current in accordance with the present invention.

FIG. 13 is a representation of a confusion matrix for KNN classification in the connected configuration using a current according to the present invention.

FIG. 14 is a representation of a confusion matrix for Random Forest model classification in the connected configuration using a current according to the present invention.

FIG. 15 is a representation of a confusion matrix for Xg Boost model classification in the connected configuration using a current according to the present invention.

FIG. 16 is a block diagram of the software that incorporates the computer-implemented method according to the present invention.

FIG. 17 is a representation of a screen of the software that incorporates the method showing the data acquired from EMACS and the main engine information, according to the present invention in operation.

FIG. 18 is a representation of a screen of the diagnostic system developed and obtaining valid results, according to the present invention.

FIG. 19 is a representation of a diagnostic screen expanded to higher frequencies according to the present invention.

### DETAILED DESCRIPTION OF THE INVENTION

Specific embodiments of the present disclosure are described below. In an effort to provide a concise description of these embodiments, all features of an actual implementation may not be described in the specification. It should be appreciated that in the development of any actual implementation, as in any engineering or design project, numerous implementation-specific decisions must be made to achieve the specific objectives of the developers, such as compliance with system-related and business constraints, which may vary from one implementation to another. Furthermore, it should be appreciated that such a development effort may be complex and time-consuming but would nevertheless be a routine design and manufacturing undertaking for those of ordinary skill having the benefit of this disclosure.

The proposed present invention consists of a computer-implemented method, including artificial intelligence machine learning techniques and libraries for graphical generation and analysis. The method of the present invention also includes communication with a device and acquisition of motor data (voltage, current, temperature, relative humidity, and vibration), data storage and processing, and the issuance of diagnostics of the operating status and condition of the motor.

The method of the present invention is executed within a computing environment comprising an Intelligent Electric Motor Diagnostics (DIME) system. DIME is an Artificial Intelligence-based, fully automated, and completely verticalized electric motor fault diagnosis solution. The system consists of:
i) sensors that capture motor vibration and ambient temperature and humidity;
ii) a hardware system for sampling and preprocessing the electrical signals of the motor;
iii) artificial intelligence-based diagnostic software; and
iv) a high-performance server with multiple functions.

The server houses the services responsible for storing data obtained by vibration, temperature, and humidity sensors, data generated by preprocessing hardware, a platform for viewing historical equipment information, and a BI web interface for management and reporting, with cross-platform access.

More generally, DIME consists of four parts:
a) Temperature, vibration, and humidity acquisition module, called MotorTAG;
b) Acquisition hardware, called EMACS (Electric Machine Acquisition System);
c) Portable processing software containing the computer-implemented method according to the present invention, called ProDiSys (Processing and Diagnosis System);
d) Server for storing failure history, accessing raw data, and consolidating BI information, called BIA Server (Business and Artificial Intelligence).

The difference between the computer-implemented method according to the present invention and the state of the art is the implementation of machine learning and artificial intelligence in addition to the current signature technique for defect analysis, failure prediction and prescription of mitigating actions.

This invention will add value to the production chain of processes that use motors by prescriptively detecting defects and their severity, such as: Improved failure analysis and diagnosis; Support in decision-making; Greater autonomy for field teams; Faster and more assertive diagnosis; Reduced costs with corrective and predictive maintenance; Scheduled maintenance shutdowns; Mitigation of production losses.

Field data, historical analysis of motors, and their behavior are stored in a database, fostering the continuous identification of new faults and corrective actions in an integrated manner, through continuous learning proposed by data interaction. Similarly, new studies can be conducted by acquiring fundamental variables, in addition to voltage and current, such as temperature, vibration, and humidity, to infer motor failure prediction. These variables will enable the identification of faults and critical situations previously dependent on specialist interpretation, enabling correlational analysis between areas, equipment, and applications.

The computer-implemented method according to the present invention also has the function of pre-analyzing the acquired voltage and current field data, allowing the field professional to verify whether the voltage and current phasor diagram is correct. If not, it provides the field professional with the opportunity to acquire new data to compose the motor database, promoting greater reliability in motor health prescriptions.

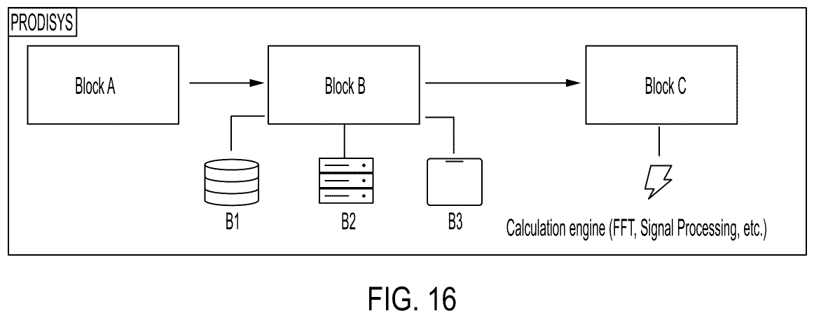

ProDiSys is an integral and most important part of the DIME system. It is through the ProDiSys intelligence software that the predictive diagnosis analysis of faults in three-phase induction motors is performed. The ProDiSys block diagram is shown in FIG. 16, identifying the modules that comprise the software.

Block A: communication module with EMACS, the acquisition hardware that performs sampling and pre-processing of signals captured by the current, voltage, and vibration sensors of the motors and by the ambient temperature and humidity sensors.

Block B: Graphical interface that displays to the user the data captured by the sensors, among other information, in conjunction with data from the SQLITE database libraries (B1), equipment registration information (B2), and reports (B3).

Block C: This is the block that executes the computer-implemented method according to the present invention, including integration with Artificial Intelligence and a calculation engine based, for example, on Fast Fourier Transform (FFT) and/or signal processing, but not limited to these.

Consists of Block A (Communication module with EMACS), through a communication link such as a Wi-Fi link generated by an access point “hidden” by EMACS itself, but not limited to this. The graphical part (Block B) has an SQLITE database, a screen and equipment registration, and also generates the final reports and makes them available to the end user.

To develop the Artificial Intelligence algorithm (Block C), a comprehensive review of the scientific literature was conducted. The main trends and methodologies were identified in the use of Artificial Intelligence for fault identification in electric motors. Valuable insights, such as the effectiveness of specific algorithms and innovative approaches that can be applied in this context, were highlighted.

A detailed analysis of different machine learning algorithms, including neural networks, support vector machines (SVMs), and decision trees, provided an in-depth understanding of their advantages and limitations. This critical evaluation allowed to select the most appropriate algorithm for this specific application, ensuring an accurate and effective fault detection approach.

Classic machine learning classification algorithms were applied, such as K-Nearest Neighbors (KNN), Logistic Regression, Gaussian Naive Bayes, Random Forest, Support Vector Machines (SVMs), and Extreme Gradient Boosting (XGBoost). The objective was to classify rotor bar failures into four categories: Healthy (0), Low Severity (1), Medium Severity (2), and High Severity (3). The preferred model used was Random Forest and trained with the data described above.

The main application of the computer-implemented method of the present invention is the identification of a fault caused by a broken bar in a three-phase motor. For the analysis of broken bar faults, an innovative method was created that allows the training of machine learning algorithms with little data. Since it is difficult to collect data from motors with broken bars in sufficient quantity to train such algorithms, a method was proposed that, in its training phase, combines noise data extracted from real motors with data from simulated motors to increase the amount of training data and generalize the learning of the method to new motors. Thus, a series of more realistic artificial data could be generated and used to train the machine learning algorithms to classify a motor into one of the following four classes: 0, 1, 2, or 3, representing, respectively, the identification of 0 (healthy), 1 (low severity), 2 (medium severity), or more (high severity) broken bars.

Three different datasets were used: one artificially generated from simulations and two real datasets obtained from public repositories. The artificial dataset was always used in training, along with noise extracted from the healthy real data. The two real datasets were exchanged: one was used to generate noise during training, the other as a test set, and then they reversed roles, following a cross-validation scheme with two subsets. It should be noted that, during the training process, the real data were not used directly to train the models; they served only to add noise to the artificial data. The test set, on the other hand, consisted of real data, which allowed to evaluate the performance of the models.

Feature extraction from the frequency spectrum of the (current) signals also explored an innovative combination of measures to ensure automated detection of the number of broken bars. To capture the different fin shapes representing this type of defect around the fundamental frequency of the signal, two windows, one to the left and one to the right of the fundamental frequency of the current, are extracted from the signal, and seven features are calculated for each: window mean value, window standard deviation, maximum window value, minimum window value, window kurtosis, and window skewness. Thus, 14 signal features are used as input to the machine learning algorithm responsible for determining the presence of broken bars, in addition to data collected by ambient temperature and humidity sensors. Studies have demonstrated the effectiveness of the proposed method in detecting broken bars. The integration of the sensors being described allows for real-time data collection, providing a solid foundation for the early identification of possible failures in three-phase electric motors.

The window limits are not fixed values but rather calculated from an equation indicated below (eq. 1). This equation determines the position of the frequency component characteristic of the bar-break fault, based on some provided parameters. The window boundaries are calculated by establishing minimum and maximum values for motor slip and assuming K=1.

Next, the methodology used to select the above parameters, as well as the AI, will be described.

### Methodology

As mentioned, there are many fault monitoring methods that can be classified as invasive or non-invasive. Invasive techniques, such as vibration and magnetic flux, require special sensors to be connected internally to the motor. Non-invasive techniques, such as motor current, speed, torque, acoustic signal, and instantaneous power, do not affect the internal structure of the motor.

These techniques, used alone, have proven to lose information and do not allow for accurate quantification of the fault. However, techniques based on motor current signature analysis (MCSA) have proven effective in detecting several induction motor faults. Therefore, a new classification is proposed for detecting broken bars, based on the current signature and signal processing methods.

Several theoretical studies have established a frequency signature component for each type of fault. Broken bar faults in induction motors exhibit characteristic frequencies f_{b}, which are given by.

$${f}_{b} = ( 1 \pm 2 ks ) {f}_{s} , k = 1 , 2 , 3 , ... \qquad ( 1 )$$

where, fₛ is the fundamental power frequency and s is the motor slip at the time of measurement. Commonly used values were 0.5% for minimum slip and 5.5% for maximum slip.

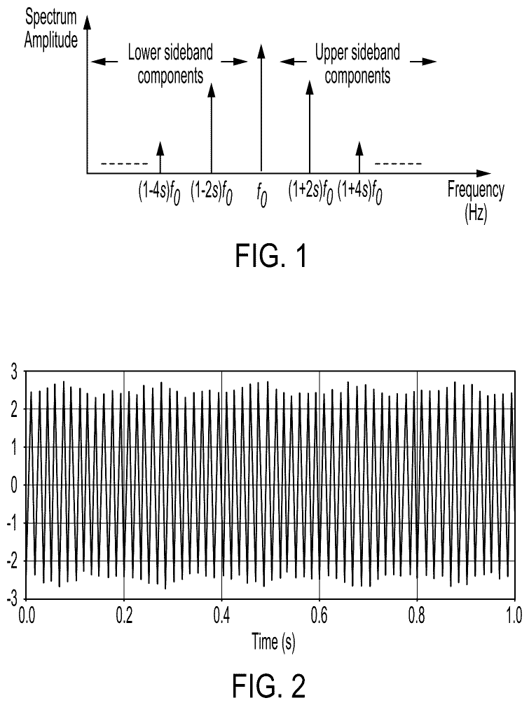

Current harmonics can be observed in the sideband harmonics around the power frequency. First-order sidebands, as shown above at (K=1), are of particular importance for detecting broken rotor bars, as shown in FIG. 1. The physical position of the broken bars, speed, and load affect the amplitudes and presence of the sidebands. Increasing motor speed and load will shift the locations of the sidebands outward.

The classical signal processing approach to broken bar fault detection for induction motors studies the sideband harmonics of the motor current around the fundamental power frequency (f0). To achieve this, the stator current is sampled over a certain time interval, then the FFT transforms the discrete time-domain data into the frequency domain to analyze the effect of broken bar failure on the stator current. An accurate slip(s) estimate is necessary to extract the fault frequencies from the stator current spectrum using the FFT. This signal processing method has some drawbacks during motor startup and in low-slip, no-load situations, which are not a problem given that we are operating with the motor at steady state and torque above 50%.

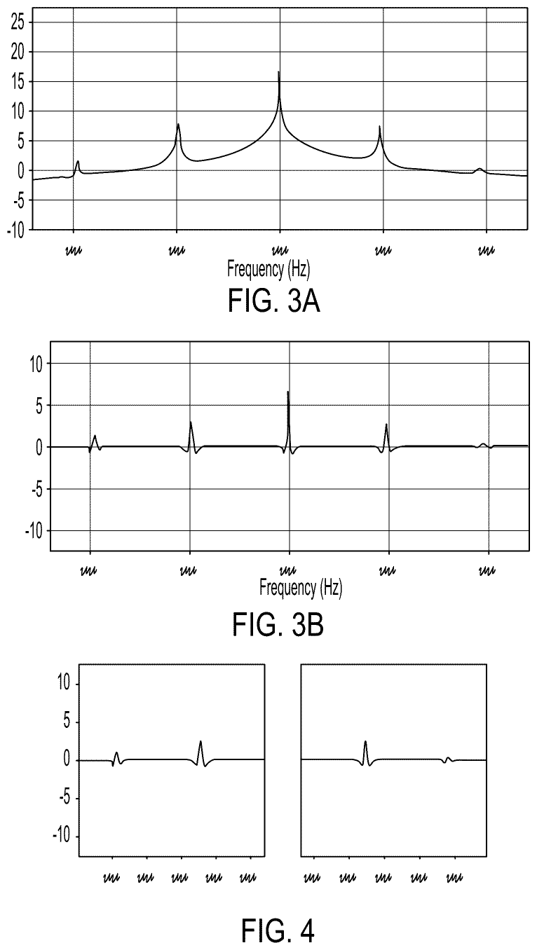

That said, using a motor with four broken bars as an example, the signal processing was performed as follows:
1. Extraction of the MCSA (FIG. 2); and
2. Application of the FFT (FIG. 3A).

The processing could end here, however, since there is no information about the motor slip at the time of the measurement, finding the position of the sidebands required more steps:
3. Flattening the FFT (FIG. 3B);
In this step, the frequency signal was preprocessed using a sliding window of size 7 (i.e., a window containing 7 samples), wherein the value of the center point of the window is subtracted by the window mean. For the first and last three points of the frequency spectrum of the signal, the window was padded with zeros on the left and right, respectively. With this transformation, the sidebands were highlighted, thus facilitating their location in the next step:
4. Windowing (FIG. 4)
Finally, the previous signal was divided into two windows, separating the sidebands from the fundamental power frequency, that is, excluding the fundamental power frequency. Thus, simply searching for the maximum point in each window is enough to find the position of the first-order sidebands.

From this, it was possible to define the features to be used in the models at this time. They are:
A) Maximum window amplitude, normalized by the amplitude of the fundamental frequency;
B) Minimum window amplitude, normalized by the amplitude of the fundamental frequency;
C) Average of the window points; and
D) Standard deviation of the window points.

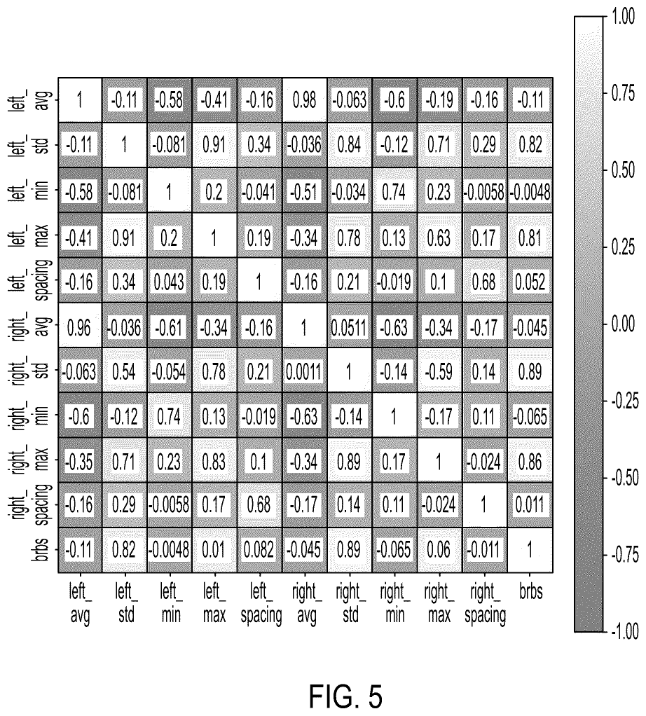

Since there are two windows (as seen in FIG. 4), there were eight parameters in total, which proved to be quite consistent. The maximum amplitude and standard deviation correlate highly with the number of broken bars, as expected. To generate FIG. 5, only the real dataset, which includes one machine/motor, was used. Other features include: Kurtosis and Skewness (statistical measures) and spacing (distance from the maximum point to the fundamental frequency).

### Machine Learning Models

Since the project focuses on current analysis to create a classification system for BRB (broken rotor bars), some traditional machine learning models (classifiers) were chosen. Among them are the artificial neural network, Knearest Neighbors, Random Forest, Xgboost, and SVM (Support Vector Machine). All were implemented in Python using several available open-source libraries.

For the neural network, the TensorFlow library with three layers was used: one input layer, one output layer, and an intermediate layer (30 neurons in the intermediate layer). For all other models, parameter search with a validation set was used before actual training to find the best parameters for each model and thus generate the best results (Xgboost belongs to an open-source library of the same name, and the other two models are from the scikit-learn library).

### Databases

Two types of data were used for this study: real and simulated. The first was obtained through studies conducted in the literature of the following publication: Experimental database for detecting and diagnosing rotor broken bar in a three-phase induction motor (2020), Aline Elly Treml, Rogério Andrade Flauzino, Marcelo Suetake, Narco Afonso Ravazzoli Maciejewski (ALI2020). The second was obtained through a MATLAB/SIMULINK simulation that generates current and voltage data for three-phase induction motors. A total of 336 simulated data sets from seven different motors were used. Another real data reference was An intelligent monitoring system for online induction motor fault diagnostics (2019), Peter Luong.

The experimental base at ALI2020 consists of a three-phase induction motor:
Induction motor: 1 HP, 220V/380V, 3.02 A/1.75 A, 4 poles, 60 Hz, nominal torque of 4.1 Nm and speed of 1715 rpm. The rotor consists of 34 bars.
Torque: The motor varies its torque from 12.5, 25, 37.5, 50, 62.5, 75, 87.5 up to 100%.
Broken bar: To simulate motor failure, it was necessary to drill holes in the rotor. Four rotors were tested: first one with one broken bar, then a second with two broken bars, and finally a rotor with four broken bars.

All signals were measured for 20 seconds for each torque condition, and 10 repetitions were performed from transient to steady state.

In total, there are 400 samples (10 for each torque and condition) from healthy to 4 broken bars.

Through experiments, the results indicated in this disclosure were generated.

### Currents

The database was made more robust with the acquisition of current data. Since there are 3 currents for each motor (IA, IB, IC), the FFTs of the 3 currents were averaged, generating a total of 7 combinations: IA with IB; IA with IC; IB with IC; and IA with IB and IC, adding the 4 new ones. With these new currents, they can be used, as long as they are in the same training, validation, and testing division (as explained later), to perform experiments with the classifiers. To generate results that avoid false hits or errors, a vote is taken among the currents used in the same sample to generate the classifications themselves. When evaluating a specific motor, each current signal is evaluated individually by the model. Then, a majority vote is performed, in which all samples are given the same weight, aiming to unify the results. This process is similar to the evaluation performed in ensemble models.

### Digital Models

It is important to note that, initially, the data obtained through the MATLAB/SIMULINK simulation were obtained from only one defective induction motor model. Therefore, to increase the range of simulation results and thus improve the efficiency of the bar breakage identification strategy, new digital induction motor models were developed. Therefore, field construction data for induction motors (specific data) were used, and new models were developed.

### Experiments

Initially, the field construction data for induction motors among the equipment that had profiles of interest were analyzed, selected, and simulated to verify the validity of the developed digital models. After data validation, the following steps could be developed. The experiments consisted of testing whether the selected features made sense and whether they could be used to classify whether a three-phase induction motor had broken bars.

After preprocessing (generating FFT, normalizing, and extracting parameters) the data from the real and synthetic databases, these databases were divided into different configurations, each representing a configuration tuple: number of currents used/type of division.

In each configuration, there is a type of division (forming the folds), by torque, by machine speed, and artificial data generated by the mathematical model that simulates the motor against the real data extracted from ALI2020.

In divisions by torque, data with the same torque are in the same fold, simulating the event of there not being a certain torque in the base.

In machine-run splits, the training set contains instances from the entire database and is used as an upper bound.

In the latter type of split, synthetic data is used for training, while real data is used for testing. In this case, the performance of the system is evaluated in the absence of real data for training.

With each configuration divided into its respective folds, experiments were performed to generate the results. To make the most of the splits, the best parameters for each classifier were chosen before training and testing. Once this was done, one fold at a time was selected and used for testing, with all other folds in that split being used to train the classifiers (KFold).

### Results

The results generated from the experiments allow for an analysis of the proposed modeling. We started using the FFT of the current signal with base-2 logarithm (as seen in “Current signature analysis to detect induction motor faults”, 2000, William T. Thomson, Mark Fenger), but the results were not satisfactory, and in some cases the broken bar problem was not evident. Therefore, the idea was abandoned and used only the FFT of the signal and extracted the parameters mentioned above.

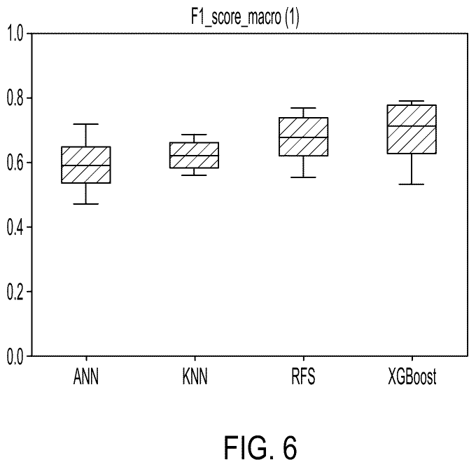

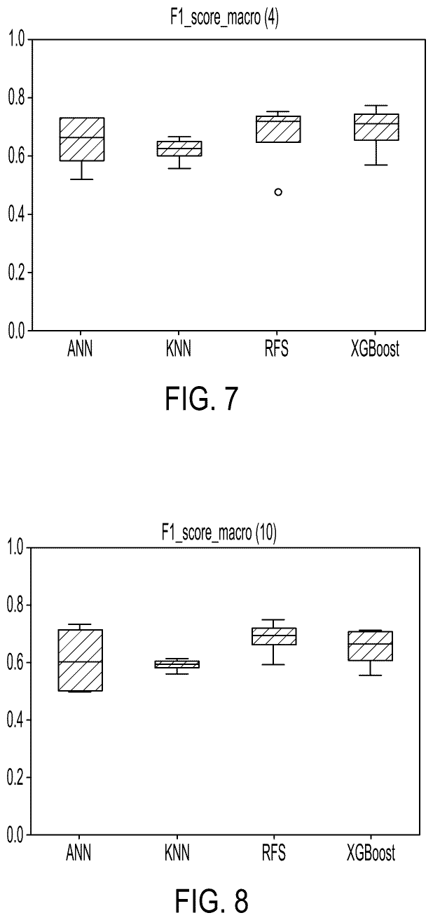

Boxplot: Using the metrics calculated for the set of outputs of each classifier and summarizing these metrics (generated at each fold of the K-Fold), a graph was generated that indicates the distribution of these results. FIGS. 6, 7, and 8 are examples of these boxplots for a current, voting among three currents, and average, using the F1 Score macro, division by torque of multiclass classifications (0 to 4), where 0 indicates no broken bars, 1 indicates one bar, 2 indicates two bars, and so on for three or more broken bars.

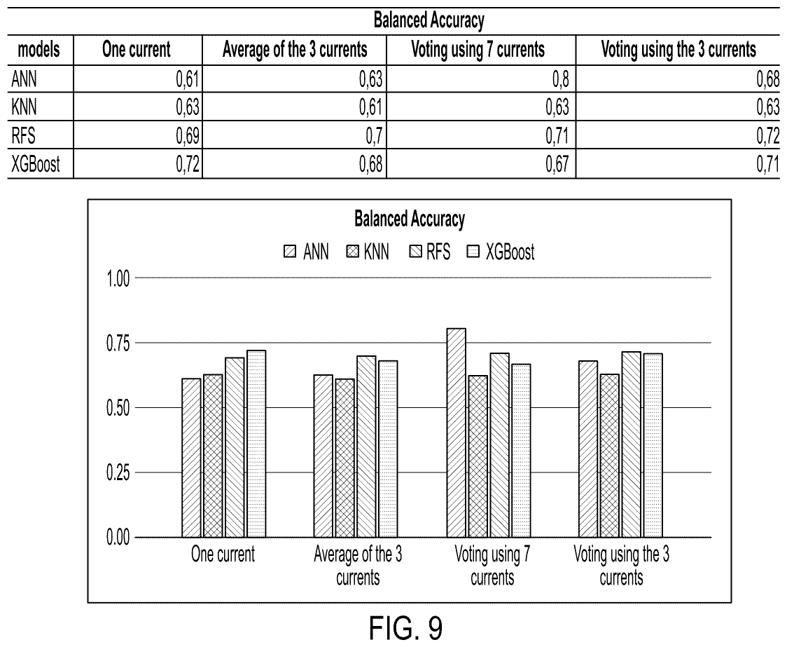

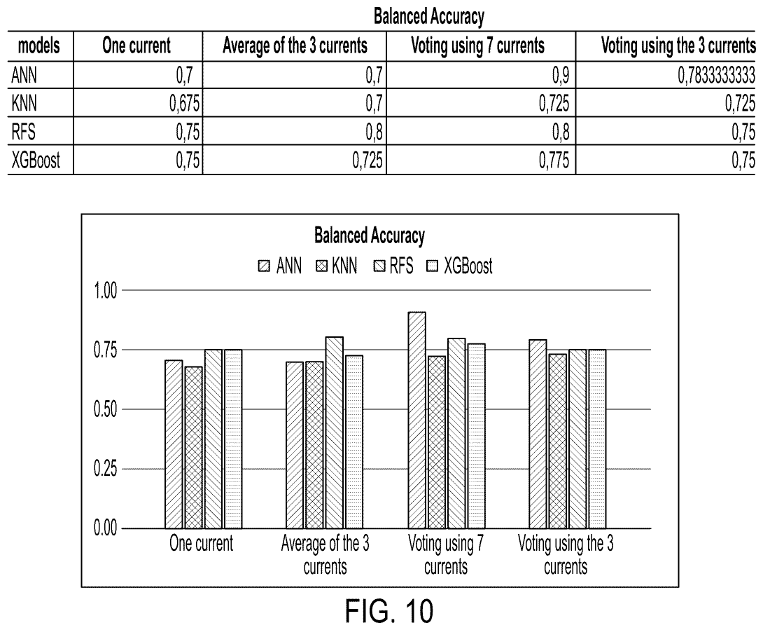

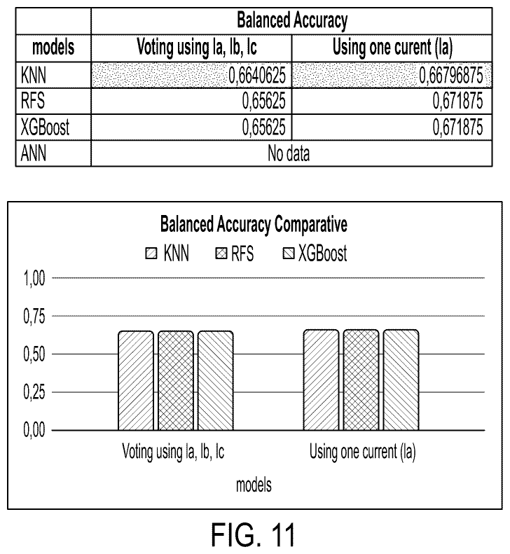

The following graphs show the percentage of success for each technique chosen for the analysis (x-axis) and its success rate (y-axis). The median of each metric in the tested K-Folds, for each model and current arrangement, is compared to find the best technique among the different experiment configurations. FIGS. 9, 10, and 11 show the bar graphs of the different configurations by torque, by on, and artificial versus real, respectively. FIGS. 9 and 10 show results for 5 classes (normal and 1 to 4 broken bars), while FIG. 11 shows the results for two classes (normal versus defective), since the results for 5 classes of the last configuration are not yet ready.

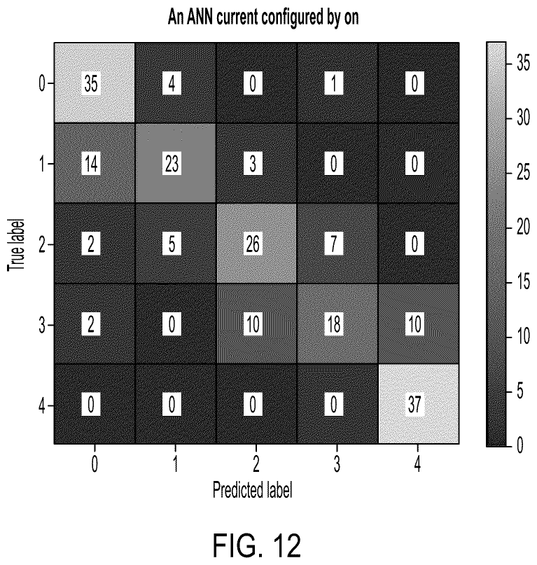

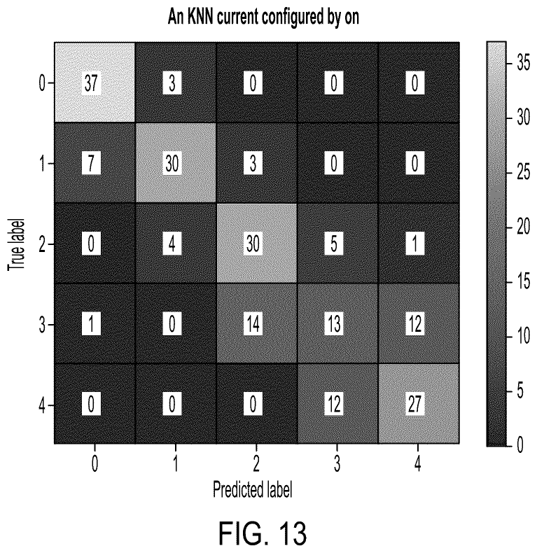

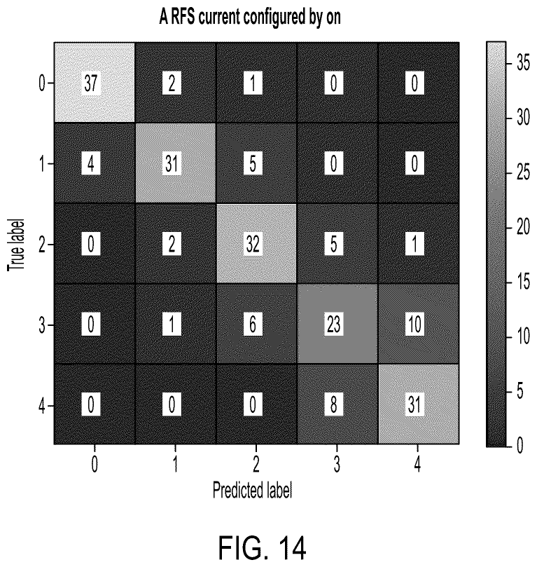

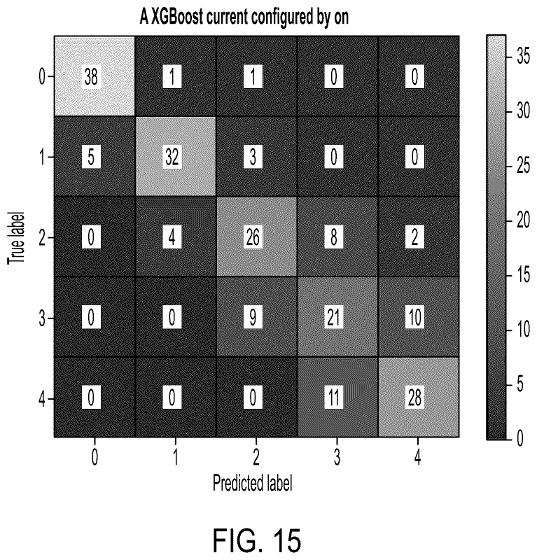

Confusion Matrix: Using the model outputs, a confusion matrix is created with the results, showing which class the machine learning models are classifying. Here, multiclass classification (0 to 4) was used, where 0 indicates no broken bars, 1 indicates one bar, and 2 indicates two bars, and so on, up to 4, which indicates 4 or more broken bars. Each experiment configuration generates one of these matrices (48 in total, as there are 4 classifiers for 12 configurations). FIGS. 12, 13, 14, and 15 are examples of the best results obtained in the tables above for each model. The x-axis represents the classifications of the model, and the y-axis represents the actual class values. The diagonal of the matrix shows how accurate the classifier was; any value outside of this range represents a classification error.

### CONCLUSIONS

It was concluded that the best classification method, probably for reasons that will be explained in more detail below, is based on decision trees. Both the Random Forest and XGBoost models have relatively superior results.

Summing up everything, it was concluded that the models have potential if the amount of data increases considerably. However, configurations that cross-reference data based on real data and synthetic data currently show unsatisfactory results. It is expected that, as the amount of data increases, the models will be able to extrapolate better prediction.

### Information Presentation

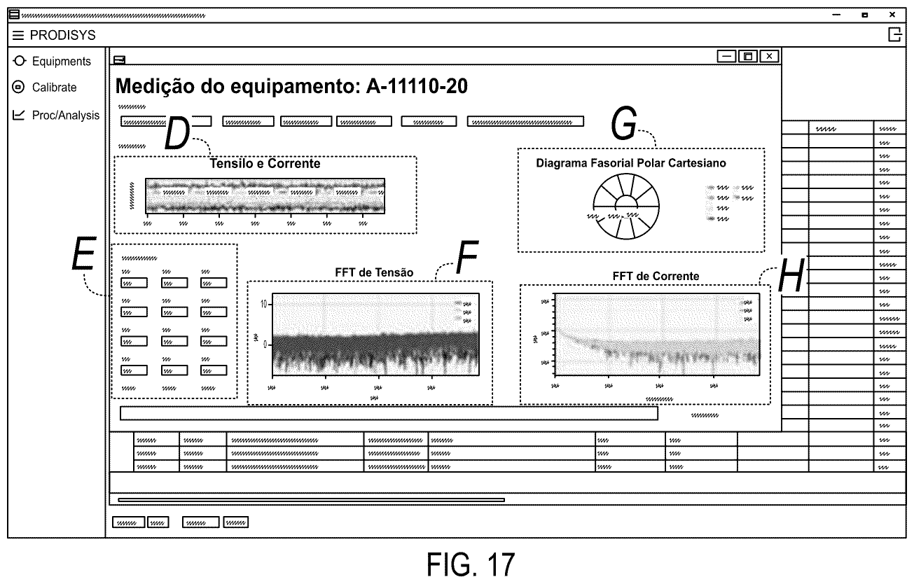

FIG. 17 shows an example ProDiSys screen showing the data acquired from EMACS and the main information about the three-phase electric motor under analysis. This example screen displays the following.

FIG. 17 (D): Time graphs of voltage and current data for each phase, i.e., time graphs of the amplitude of IA, IB, IC, VA, VB, and VC.

FIG. 17 (E): Instantaneous value indicators for IA, IB, IC, VA, VB, and VC; Power Factor for each phase; FPA, FPB, FPC; Total Harmonic Distortion (THD) for IA, IB, IC, VA, VB, and VC.

FIG. 17 (F): FFT of each voltage VA, VB, VC.

FIG. 17 (G): Cartesian polar phasor diagram of IA, IB, IC, VA, VB, and VC.

FIG. 17 (H): FF of each current IA, IB, and IC.

It is worth noting that prior to the study, development, and testing of the IA algorithm, extensive study and creation of the computational mathematical model of three-phase induction motors was required. This model was extremely versatile and capable of simulating several types of faults, such as: stator asymmetry, squirrel-cage rotor asymmetry, eccentricity, and mechanical faults.

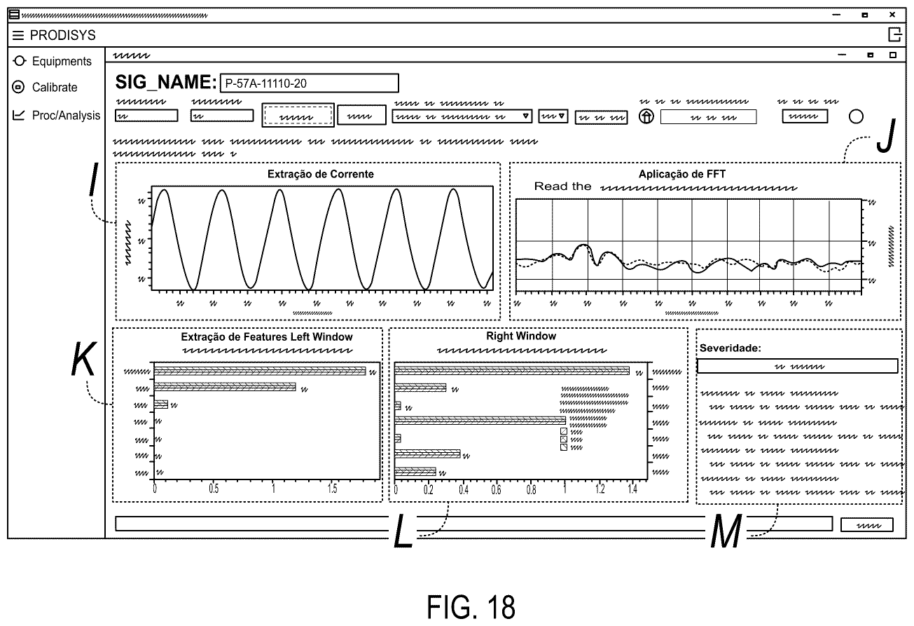

FIG. 18 shows an example ProDiSys screen showing the following.

FIG. 18 (I): Amplitude versus time graph of the current of one of the phases being considered: IA, IB, or IC.

FIG. 18 (J): Amplitude versus frequency graph of the FFT of the phase considered in I.

FIG. 18 (K): Calculated values of the window to the left of the time instant considered for the window mean value (avg), window standard deviation (std), maximum window value (max), minimum window value (min), window kurtosis (kurt), and window skewness.

FIG. 18 (L): Calculated values of the window to the right of the time instant considered for the window mean value (avg), window standard deviation (std), maximum window value (max), minimum window value (min), window kurtosis (kurt), and window skewness.

FIG. 18 (M): Determination, according to the method of the present invention, of a probability of a non-existent broken bar fault of low, medium, or high severity for each of the phases of the three-phase electric motor considered.

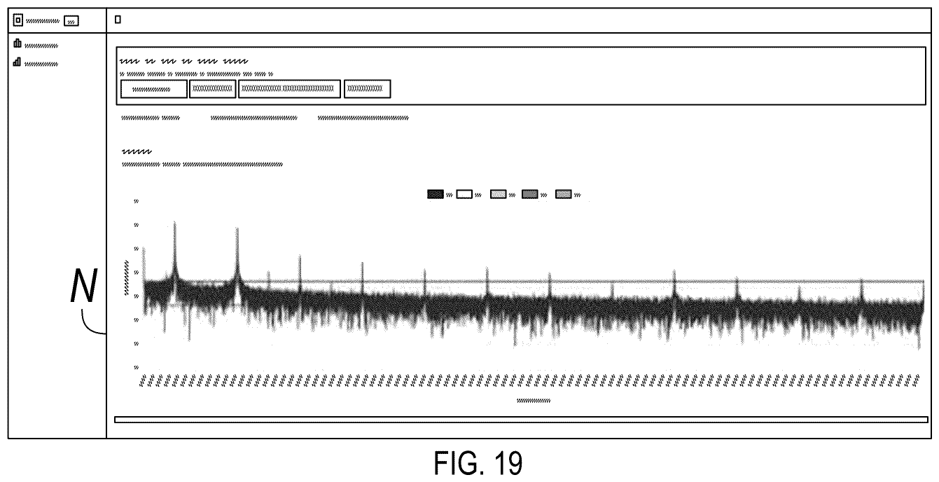

FIG. 19 shows an example diagnostic screen expanded to higher frequencies, demonstrating the expandability of the solution as a customization possible with the developed system, unlike the sealed structures found in commercial systems available on the market. FIG. 19 (N), in this example, is an amplitude versus frequency plot of the FFT of the eccentricity of Phase A, in blue, also showing the average in green, average +15 dB in yellow, average +20 dB in red, and Phase A in crimson.

While aspects of the present disclosure may be susceptible to several modifications and alternative forms, specific embodiments have been shown by way of example in the drawings and have been described in detail herein. However, it should be understood that the invention is not intended to be limited to the particular forms disclosed. Rather, the invention should cover all modifications, equivalents, and alternatives that fall within the scope of the invention, as defined by the following appended claims.

What is claimed is:

1. A computer-implemented method for predicting a broken bar defect in a three-phase motor, comprising:
obtaining current and voltage data for each phase of the three-phase motor;
performing Fast Fourier Transform (FFT) for each current and then flattening the FFT;
performing a three-point windowing to a left and a right centered on a fundamental frequency;
for each window, calculating a mean value, a standard deviation, a maximum value, a minimum value, a kurtosis, a skewness, and a spacing;
using the calculated mean value, standard deviation, maximum value, minimum value, kurtosis, skewness, and spacing as input data in a previously trained Artificial Intelligence; and
determining, using the previously trained Artificial Intelligence, a probability of a broken bar failure in each of the phases of the three-phase motor.

2. The method of claim 1, further comprising obtaining vibration data for the three-phase motor.

3. The method of claim 2, wherein the calculated mean value, standard deviation, maximum value, minimum value, kurtosis, skewness, and spacing are used as the input data in the previously trained Artificial Intelligence combined with the obtained vibration data.

4. The method of claim 1, further comprising obtaining humidity and temperature data for the environment where the three-phase motor is located.

5. The method of claim 4, wherein the calculated mean value, standard deviation, maximum value, minimum value, kurtosis, skewness, and spacing are used as the input data in the previously trained Artificial Intelligence combined with the obtained humidity and temperature data.

6. The method of claim 1, wherein the calculated mean value, standard deviation, maximum value, minimum value, kurtosis, skewness, and spacing are used as the input data in the previously trained Artificial Intelligence combined with the obtained current and voltage data.

7. The method of claim 1, further comprising determining the fundamental frequency of each current based on the FFT for each current.

8. The method of claim 1, wherein the determining of the probability of the broken bar failure comprises determining, separately for each phase, a probability of no failure, a probability of a low-severity failure, a probability of a medium-severity failure, and a probability of a high-severity failure.

9. A computer-implemented method for predicting a broken bar defect in a three-phase motor, comprising:
obtaining current and voltage data for each phase of the three-phase motor;
obtaining vibration data for the three-phase motor;
obtaining humidity and temperature data for the environment where the three-phase motor is located;
performing Fast Fourier Transform (FFT) for each current and then flattening the FFT;
determining a fundamental frequency of each current based on the FFT for each current;
performing a three-point windowing to a left and a right centered on the fundamental frequency;
for each window, calculating a mean value, a standard deviation, a maximum value, a minimum value, a kurtosis, a skewness, and a spacing;
using the calculated mean value, standard deviation, maximum value, minimum value, kurtosis, skewness, and spacing as input data in a previously trained Artificial Intelligence, combined with the obtained current and voltage data, the obtained vibration data, and the obtained humidity and temperature data; and
determining, using the previously trained Artificial Intelligence, a probability of a broken bar failure in each of the phases of the three-phase motor.

10. The method of claim 9, wherein the determining of the probability of the broken bar failure comprises determining, separately for each phase, a probability of no failure, a probability of a low-severity failure, a probability of a medium-severity failure, and a probability of a high-severity failure.
